(19) United States
(12) Patent Application Publication
(10) Pub. No.: US 2015/0360934 A1
(43) Pub. Date: Dec. 17, 2015

(54) Microelectromechanical system and method for manufacturing a microelectromechanical system

(71) Applicant: Robert Bosch GmbH, Stuttgart (DE)

(72) Inventor: Florian Grabmaier, Tuebingen (DE)

(21) Appl. No.: 14/740,462

(22) Filed: Jun. 16, 2015

(30) Foreign Application Priority Data
Jun. 17, 2014 (DE) 10 2014 211 558.2

(51) Int. Cl. B81B 7/00; B23K 20/02; H05K 1/11; H05K 3/32; B81C 1/00; H05K 1/18

(52) U.S. Cl. CPC B81B 7/0006; B81C 1/00301; H05K 1/181; H05K 1/11; H05K 3/32; B23K 20/023; B81B 7/0035

(57) ABSTRACT

A microelectromechanical system includes a microelectromechanical element and a substrate, in which an element surface of the element and a substrate surface of the substrate is integrally joined with the aid of an eutectic alloy at at least one joint. Also described is a method for manufacturing a microelectromechanical system.

### RELATED APPLICATION INFORMATION

The present application claims priority to and the benefit of German patent application no. 10 2014 211 558.2, which was filed in Germany on Jun. 17, 2014, the disclosure of which is incorporated herein by reference.

### FIELD OF THE INVENTION

The present invention relates to a microelectromechanical system as well as to a method for manufacturing a microelectromechanical system.

### BACKGROUND INFORMATION

In order to equip microchips with a large number of IOs (input/output connections) on a carrier substrate and to electrically contact them, flip chip technology or wire bonding is usually used. Flip chip is used for up to several hundred contacts, while wire bonding may also be used for more contacts, but costs increase with the number of the electrical connections since they are established sequentially.

However, there are several particularities in the case of MEMS (micro-mechanical systems). They typically contain sensitive micromechanical structures or elements which may be destroyed when injecting ultrasonic energy which is used for wire bonding. Moreover, they often require access to the outside world in order to guide the variable to be measured from the environment to the MEMS element.

### SUMMARY OF THE INVENTION

An object of the present invention may therefore be seen in providing a microelectromechanical system which may be manufactured easily and cost-effectively.

The object underlying the present invention may furthermore also be seen in providing a corresponding method for manufacturing a microelectromechanical system.

These objects are achieved with the aid of the respective subject matter of the independent claims. Advantageous embodiments of the present invention are the subject matter of the respective subclaims.

According to one aspect, a microelectromechanical system (MEMS) is provided, including:
a microelectromechanical element and
a substrate,
an element surface of the element and a substrate surface of the substrate being integrally joined with the aid of an eutectic alloy at at least one joint.

According to another aspect, a method for manufacturing a microelectromechanical system (MEMS), in particular for manufacturing a MEMS according to the present invention, is provided, including the following steps:
providing a microelectromechanical element and a substrate,
integrally joining an element surface of the element and a substrate surface of the substrate with one another at at least one joint with the aid of an eutectic alloy.

The present invention therefore includes in particular the idea of providing an eutectic alloy, which integrally joins the element surface with the substrate surface, between the element surface and the substrate surface. This means that the element and the substrate are integrally joined with one another. Another particular advantage is that an eutectic bonding may be carried out due to the eutectic alloy, force being exerted during this process. A great number of contacts may thus be created across a large area in an advantageous way even when they would no longer touch one another by mere placement due to flatness tolerances. The classic flip chip process cannot offer or effectuate that. In particular, pressing is thus important in the process. Alternatively or additionally, a pressure sintering process may also be provided.

According to one specific embodiment it is provided that at least one joint is electrically connected to an electrical contact of the element. In this way in particular the technical advantage is effectuated that the element may be electrically contacted via the joint. Electrical signals of the element may thereby be transmitted in an advantageous way away from the element via the joint. In particular electrical signals may be supplied in an advantageous way to the element via the joint. It is also possible to thus provide an electrical power supply in an advantageous way via the joint. An electrical contact may be an I/O contact (input/output contact), for example.

According to another specific embodiment it is provided that at least some joints are situated in a grid structure. By providing such a grid structure, in particular the technical advantage is effectuated that manufacturing is particularly simplified due to the regularity of the joints caused by the grid structure.

In another specific embodiment it is provided that a joint is formed having an intrinsically closed shape and surrounding the remaining joints, so that a hermetic seal is formed for the remaining joints with the aid of the substrate, the element and the intrinsically closed joint. In this way, in particular the technical advantage is effectuated that the remaining joints are hermetically encapsulated from the outside world. In this way, the microelectromechanical system may, for example, be used in an advantageous way in severe environmental conditions.

According to another specific embodiment it is provided that the substrate includes at least one via electrically connected to one joint (which may be multiple joints) for an electrical connection between the substrate surface and an additional substrate surface situated opposite the substrate surface. In this way in particular the technical effect is effectuated that an electrical power supply or an electrical signal transmission for or by the element may also be provided by the additional substrate surface. The electrical signals or the electrical power supply may be provided to the joint with the aid of the via.

In another specific embodiment it is provided that at least one component electrically connected to the via is situated on the additional substrate surface. In this way the technical effect is effectuated that the additional substrate surface may be used efficiently as an installation area for a component, for example. In this way in particular the technical advantage is effectuated that an electrical connection between the component and the joint is established. In particular when the joint is additionally also electrically connected to an electrical contact of the element, the technical advantage may be effectuated, for example, that an electrical connection between the component and the element is effectuated.

According to another specific embodiment, the component is an element selected from the following group of components: processor (IC, “integrated circuit”), battery, chip, passive components. Passive components are, for example: resistor, capacitor, coil.

In another specific embodiment it is provided that the component is hermetically sealed with the aid of a cap. In this way in particular the technical advantage is effectuated that the component is reliably encapsulated from an outside world or the surroundings. In this way, the microelectromechanical system, for example, may be used in severe environmental conditions. The component is protected against damage by the cap. The cap is made of metal, for example.

In another specific embodiment it is provided that the cap is soldered to and/or welded onto the additional substrate surface. In this way in particular the technical effect is effectuated that a particularly reliable connection or fastening of the cap to the additional substrate surface is effectuated. In this way in particular the technical effect is effectuated that a durable connection between the cap and the additional substrate surface is effectuated. This connection is thus mechanically particularly stable in an advantageous way.

In another specific embodiment it is provided that the element surface includes a first metal plating structure made of a first metal, the substrate surface including a second metal plating structure made of a second metal, the first metal and the second metal forming an eutectic system, the joining including the following steps:
pressing the two metal plating structures onto each other so that at least one joint is formed corresponding to the metal plating structures, and
melting of the two metals so that the molten metals form an eutectic alloy at the joint.

Eutectic alloys within the sense of the present invention have an unambiguously determinable melting point. Their melting point is also the lowest of all mixtures containing the same elements. Other mixing ratios including the same elements, on the other hand, have a melting and solidification range in which there is also a solid phase in addition to the melt. Due to the fact that all elements solidify at the same time and that this happens at a temperature which is much lower than would be the case for the pure components, a fine and uniform structure results which has a generally distinct lamellar structure. The cause for this is the low kinetic energy of the atoms at this temperature, which allows only short distances and thus the formation of only very small crystals (also called crystallites).

In another specific embodiment it is provided that the eutectic system is an element selected from the following group of eutectic systems: Indium gold (InAu), tin silver (SnAg).

Specific embodiments and features and advantages which result from the microelectromechanical system similarly apply for the method according to the present invention and vice versa. This means that specific embodiments from the method similarly result from specific embodiments regarding the system and vice versa.

According to one specific embodiment, the substrate is formed from a ceramic or includes a ceramic. The substrate may in particular be a hybrid ceramic or include such a ceramic. The substrate is, for example, an aluminum oxide ceramic substrate. In an advantageous way, such a substrate is a good insulator with little loss.

In another specific embodiment it is provided that the microelectromechanical element is an element selected from the following group of microelectromechanical elements: acceleration sensor, rotation rate sensor, pressure sensor, chip, micro-mirror, micro-mirror array or non-MEMS (micromechanical system) elements, for example, a CCD image sensor, or a CMOS image sensor.

The present invention is described in greater detail hereafter based on exemplary embodiments. Hereafter, identical reference numerals may be used for identical features.

### BRIEF DESCRIPTION OF THE DRAWINGS

FIG. 1 shows a side view of a microelectromechanical system.

FIG. 2 shows a top view onto an element surface of a microelectromechanical element.

FIG. 3 shows another microelectromechanical system.

FIG. 4 shows a flow chart of a method for manufacturing a microelectromechanical system.

### DETAILED DESCRIPTION

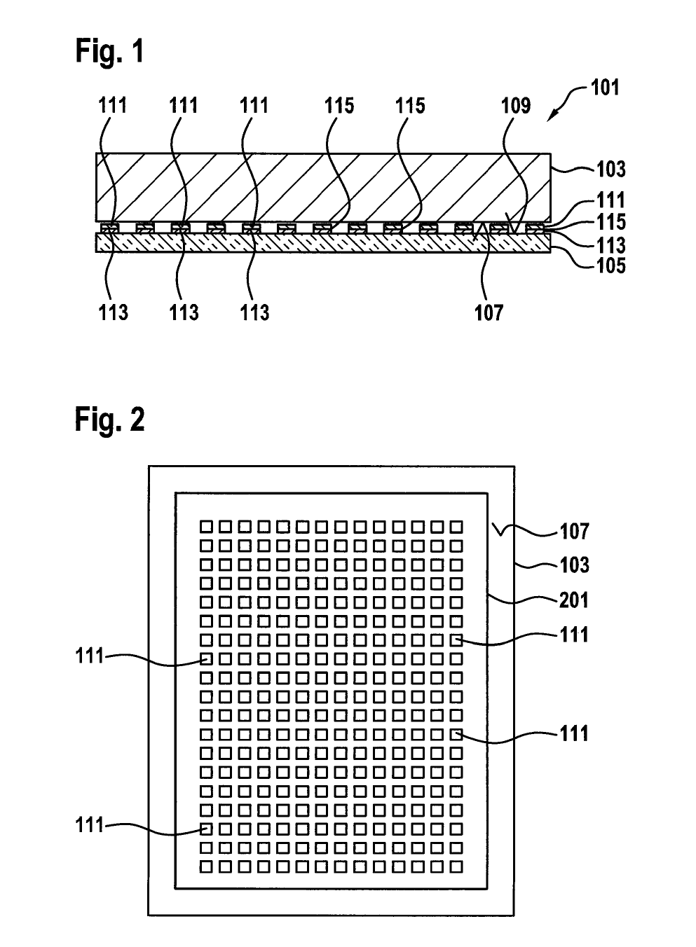

FIG. 1 shows a microelectromechanical system 101.

System 101 includes a microelectromechanical element 103 and a substrate 105 which may generally also be referred to as a substrate carrier, since it carries element 103. Element 103 includes an element surface 107. Substrate 105 includes a substrate surface 109. Multiple metal pads 111 made of a first metal are situated in a grid structure on element surface 107 (see FIG. 2). Corresponding to this grid structure, multiple metal pads 113 made of a second metal are also situated in a grid structure on substrate surface 109. First metal pads 111 form a first metal plating structure. Second metal pads 113 form a second metal plating structure. The first metal and the second metal form an eutectic system. The first metal may be indium, for example. The second metal may then be gold or vice versa.

Element 103 and substrate 105 are joined with one another by pressing the respective metal pads 111 and 113 onto each other. Joints 115 form in those areas where the corresponding metal pads 111 and 113 touch one another or make contact. By pressing them onto each other and adding thermal energy to metal pads 111, 113, metal pads 111, 113 melt and form an eutectic phase.

A melting temperature after the joining is significantly higher than an original melting temperature during the joining. After the joining, element surface 107 and substrate surface 109 are integrally connected or joined with one another at joints 115 with the aid of the formed eutectic alloy.

FIG. 2 shows an element surface 107 of a microelectromechanical element 103. Microelectromechanical element 103 is essentially similar to element 103 according to FIG. 1. The following explanations may apply similarly to element 103 of FIG. 1. The grid structure from metal pads 111 is clearly apparent. Metal pads 111 may be connected to respective electrical contacts of element 103. An electrical contacting of element 103 is thus effectuated in an advantageous way via joints 115. In addition, element surface 107 of element 103 of FIG. 2 includes a metal ring 201 made of the first metal. Metal ring 201 surrounds metal pads 111. Metal ring 201 is intrinsically closed. FIG. 2 shows that metal ring 201 has a rectangular shape. In exemplary embodiments not shown, other geometric shapes are provided. For example, a circular shape, a square shape or a polyhedron shape may be provided.

Substrate surface 109 includes, corresponding to metal ring 201 made of the first metal, a metal ring of its own made of the second metal, the shape of this metal ring corresponding to the shape of metal ring 201. This metal ring also surrounds metal pads 113 of substrate 105. When element 103 and substrate 105 including their metal pads 111, 113 and their corresponding metal rings are pressed onto each other, and heat or thermal energy is added, the metals of the metal rings also melt and also form an eutectic phase. In this way a joint is formed from an eutectic alloy in an advantageous way, which forms an intrinsically closed shape and surrounds the remaining joints 115. This effectuates in an advantageous way that the remaining joints 115, which are formed by metal pads 111, 113, are hermetically sealed or encapsulated with the aid of substrate 105, element 103 and the joint formed due to the metal rings. This means that, in particular in addition to the electrical contacting of element 103, a hermetical sealing of the interface thus formed may be achieved.

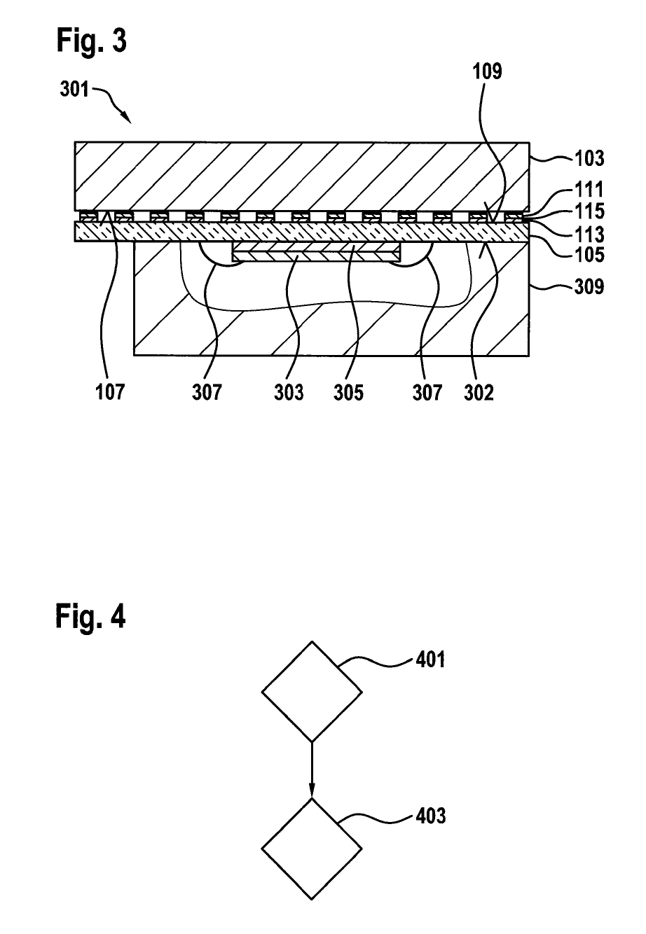

FIG. 3 shows an additional microelectromechanical system 301.

Microelectromechanical system 301 is essentially similar to microelectromechanical system 101 according to FIG. 1. A difference is that substrate 105 has a double-sided metal plating. An additional metal plating structure is formed on an additional substrate surface 302, the additional substrate surface 302 being situated opposite substrate surface 109.

This additional metal plating structure is not shown in detail here. Substrate 105 of system 301 includes multiple vias which are also not shown in detail here. These vias effectuate an electrical connection between substrate surface 109 and additional substrate surface 302. Metal pads 113 are at least partially electrically connected to these vias. An electrical contacting of element 103 is thus possible with the aid of these vias as seen from additional substrate surface 302 in an advantageous way.

A component 303 is situated on the additional substrate surface 302. Component 303 is integrally fastened with the aid of a solder layer 305 to additional substrate surface 302. Instead of or in addition to solder layer 305, an adhesive layer may be provided in a specific embodiment which is not shown. Bonding wires 307 are provided which effectuate an electrical contacting of component 303 to the metal plating of additional substrate surface 302. Bonding wires 307 may in particular be electrically connected to vias. In this way, an electrical connection is effectuated in an advantageous way between component 303 and element 103 via bonding wires 307, the vias and joints 115.

Furthermore, a cap 309 is provided which is situated on the additional substrate surface 302 and which hermetically seals component 303 from the surroundings of system 301. Cap 309 may be formed of metal, for example, or include one. Cap 309 may be welded and/or soldered on.

In summary, the present invention includes in particular the idea to produce a package (microelectromechanical system) which on the one hand may connect a plurality of electrical contacts of the microelectromechanical element to remaining electronics (for example, a component, in particular a processor), the element may be hermetically sealed by a circumferential joint, despite access to the outside world. An eutectic alloy is formed during joining. This joining technique may be referred to in particular as eutectic bonding. A number of electric contacts, for example, may be advantageously greater than 1,000. For this purpose, in particular a microelectromechanical element including electric pads, in particular, metal pads, on one reverse side, generally an element surface, is manufactured. The substrate, in particular the substrate carrier, for example, a ceramic, also includes pads, in particular, metal pads, of the same size and a grid on its top side, generally the substrate surface. The metal plating of these pads on the element and the substrate together result in a metal combination with an eutectic. This means that the two used metals of the pads are applied in an eutectic ratio, for example, indium gold. The microelectromechanical element may be a micro-mirror array, for example, which profits from such an encapsulation in particular in connection with the hermetical encapsulation.

FIG. 4 shows a flow chart of a method for manufacturing a microelectromechanical system.

In a step 401, a microelectromechanical element and a substrate are provided. In a step 403, an element surface of the element and a substrate surface of the substrate are integrally joined with one another at at least one joint with the aid of an eutectic alloy.

In a specific embodiment which is not shown, it is provided that the element surface includes a first metal plating structure made of a first metal, the substrate surface including a second metal plating structure made of a second metal, the first metal and the second metal forming an eutectic system, the joining including the following steps:
pressing the two metal plating structures onto each other so that at least one joint is formed corresponding to the metal plating structures, and
melting of the two metals so that the molten metals form an eutectic alloy at the joint.

What is claimed is:

1. A microelectromechanical system, comprising:
a microelectromechanical element; and
a substrate;
wherein an element surface of the element and a substrate surface of the substrate is integrally joined with the aid of an eutectic alloy at at least one joint.

2. The microelectromechanical system of claim 1, wherein at least one joint is electrically connected to an electrical contact of the element.

3. The microelectromechanical system of claim 1, wherein at least two joints are situated in a grid structure.

4. The microelectromechanical system of claim 1, wherein a joint having an intrinsically closed shape which surrounds the remaining joints is formed so that a hermetical seal for the remaining joints is formed with the aid of the substrate, the element and the intrinsically closed joint.

5. The microelectromechanical system of claim 1, wherein the substrate includes at least one via electrically connected to a joint for an electrical connection between the substrate surface and an additional substrate surface situated opposite the substrate surface.

6. The microelectromechanical system of claim 5, wherein at least one component electrically connected to the via is situated on the additional substrate surface.

7. The microelectromechanical system of claim 6, wherein the component is hermetically sealed with the aid of a cap.

8. The microelectromechanical system of claim 7, wherein the cap is soldered and/or welded onto the additional substrate surface.

9. A method for manufacturing a microelectromechanical system, the method comprising:
providing a microelectromechanical element and a substrate; and
integrally joining an element surface of the element and a substrate surface of the substrate with one another at at least one joint with the aid of an eutectic alloy.

10. The method of claim 9, wherein the element surface includes a first metal plating structure made of a first metal, the substrate surface includes a second metal plating structure made of a second metal, the first metal and the second metal forming an eutectic system, the joining including performing:
pressing the two metal plating structures onto each other so that at least one joint is formed corresponding to the metal plating structures; and
melting the two metals so that the molten metals form an eutectic alloy at the joint.
